(19) United States
(12) Patent Application Publication
(10) Pub. No.: US 2013/0233344 A1
(43) Pub. Date: Sep. 12, 2013

(54) METHOD FOR CLEANING SEMICONDUCTOR WAFER

(71) Applicants: Hitoshi Kabasawa, Nishishirakawa-gun (JP); Tatsuo Abe, Nishishirakawa-gun (JP)

(72) Inventors: Hitoshi Kabasawa, Nishishirakawa-gun (JP); Tatsuo Abe, Nishishirakawa-gun (JP)

(73) Assignee: SHIN-ETSU HANDOTAI CO., LTD., Tokyo (JP)

(21) Appl. No.: 13/989,605

(22) PCT Filed: Nov. 1, 2011
(86) PCT No.: PCT/JP2011/006107

§ 371 Date: May 24, 2013

(30) Foreign Application Priority Data
Dec. 16, 2010 (JP) 2010-280672

(51) Int. Cl. H01L 21/02

(52) U.S. Cl. CPC H01L 21/02041
USPC 134/3

(57) ABSTRACT

The present invention is a method for cleaning a semiconductor wafer comprising the steps of cleaning the semiconductor wafer with an SC1 cleaning solution, cleaning the semiconductor wafer cleaned by the SC1 cleaning solution with hydrofluoric acid, and cleaning the semiconductor wafer cleaned by the hydrofluoric acid with ozonated water having an ozone concentration of 3 ppm or more, wherein an etching removal of the semiconductor wafer with the SC1 cleaning solution is made 0.1 to 2.0 nm, whereby a method for cleaning a semiconductor wafer in which worsening of the surface roughness of the wafer due to cleaning can be reduced and cleaning of the wafer can be carried out effectively can be provided.

### TECHNICAL FIELD

The present invention relates to improvement of a method for cleaning semiconductor wafer.

### BACKGROUND ART

As the cleaning method of a semiconductor wafer (hereinafter also referred to as wafer simply) such as a silicon wafer, there have frequently been used a cleaning process such as an RCA cleaning using a mixed cleaning solution (hereinafter referred to SC1 (Standard Cleaning 1) cleaning solution) comprising aqueous ammonia, a hydrogen peroxide solution and ultrapure water, and a mixed cleaning solution (SC2 (Standard Cleaning 2) cleaning solution) comprising hydrochloric acid, a hydrogen peroxide solution and ultrapure water.

In the SC1 cleaning, particles attached to the surface of the wafer are removed by etching due to lift-off thereof, and to remove the particles sufficiently, it is usually required to etch the wafer 4 nm or more (Patent Document 1).

On the other hand, as one of demands for improvement of qualities accompanied by miniaturization of the design rules of apparatuses, reduction of the surface roughness of the wafer is required. The surface roughness of the wafer is usually formed by the final polishing, but due to the etching action to the wafer (silicon) by the SC1 cleaning, the surface roughness of the wafer is more worsened as the etching removal (etching amount) is larger.

If the surface roughness is worsened, it has been known that electric characteristics of an oxide film formed on the silicon wafer are worsened, or bad effects are exerted on detecting the particles by a particles counter using scattering of laser light, so that the surface roughness of the wafer is required to be as little as possible.

However, if the etching amount of the SC1 cleaning is decreased to improve surface roughness of the wafer, a cleaning power is lowered and particles are left. Thus, the particles can be removed even when the etching amount due to the SC1 cleaning solution is decreased to some extent by strengthening physical cleaning due to ultrasonic wave and improving particles-removing ability used together with the SC1 cleaning, which is used for the purpose of supplementing decrease in cleaning power due to decrease in the etching amount. However, if the etching amount by the SC1 is 2.0 nm or less, there is a problem that the particles cannot be removed and are left even when the ultrasonic wave is strengthened.

That is, in the conventional method for cleaning a semiconductor wafer, effective removal of the particles and prevention of worsening surface roughness of the wafer could not be accomplished simultaneously.

### CITATION LIST

### Patent Literature

Patent Document 1:Japanese Unexamined Patent publication (Kokai) H09-69509A

### SUMMARY OF INVENTION

The present invention has been accomplished in view of the above-mentioned problems, and an object thereof is to provide a method for cleaning a semiconductor wafer in which worsening of the surface roughness of the wafer due to cleaning can be reduced, and cleaning of the wafer can be carried out effectively.

To solve the above-mentioned problems, the present invention is to provide a method for cleaning a semiconductor wafer, which is to clean the semiconductor wafer, comprising the steps of cleaning the semiconductor wafer with an SC1 cleaning solution, cleaning the semiconductor wafer cleaned by the SC1 cleaning solution with hydrofluoric acid, and cleaning the semiconductor wafer cleaned by the hydrofluoric acid with ozonated water having an ozone concentration of 3 ppm or more, wherein an etching removal of the semiconductor wafer with the SC1 cleaning solution is made 0.1 to 2.0 nm.

Thus, in the method for cleaning a semiconductor wafer of the present invention, cleaning with the SC1 cleaning solution is carried out by decreasing the etching removal of 0.1 to 2.0 nm, so that worsening of the surface roughness of the semiconductor wafer can be prevented. Also, the particles left after the SC1 cleaning are removed by the subsequent cleaning with hydrofluoric acid, and according to the cleaning with the ozonated water having an ozone concentration of 3 ppm or more thereafter, an oxide film is formed on the surface of the wafer which makes the surface of the wafer from a hydrophobic surface to a hydrophilic surface to prevent from reattachment of the particles, so that worsening of the surface roughness of the wafer due to cleaning can be reduced and cleaning of the wafer can be carried out effectively.

As explained above, according to the method for cleaning a semiconductor wafer of the present invention, worsening of the surface roughness of the wafer due to cleaning can be reduced and cleaning of the wafer can be carried out effectively.

### BRIEF DESCRIPTION OF THE DRAWINGS

FIG. 1 is a flow chart showing an example of the method for cleaning a semiconductor wafer of the present invention.

FIG. 2 is a graph illustrating the measurement results of the particles of the surface of the wafer in Examples 1 to 5 and Comparative Examples 1 to 9.

FIG. 3 is a graph illustrating the measurement results of the surface roughness of the wafer in Examples 1 to 5 and Comparative Examples 1 to 9.

FIG. 4 is a graph illustrating the measurement results of the particles in Example 6 and Comparative Example 10.

### DESCRIPTION OF EMBODIMENTS

In the following, the present invention is explained in more detail.

As mentioned above, a method for cleaning a semiconductor wafer which can reduce worsening of the surface roughness of the wafer due to cleaning and can carry out cleaning of the wafer effectively has been demanded.

Thus, the present inventor has earnestly investigated, and as a result, it has found that a method for cleaning a semiconductor wafer which comprises the steps of cleaning the semiconductor wafer with an SC1 cleaning solution, cleaning the semiconductor wafer cleaned by the SC1 cleaning solution with hydrofluoric acid, and cleaning the semiconductor wafer cleaned by the hydrofluoric acid with ozonated water having an ozone concentration of 3 ppm or more, wherein an etching removal of the semiconductor wafer with the SC1 cleaning solution is made 0.1 to 2.0 nm, whereby worsening of the surface roughness of the wafer due to cleaning can be reduced and cleaning of the wafer can be carried out effectively.

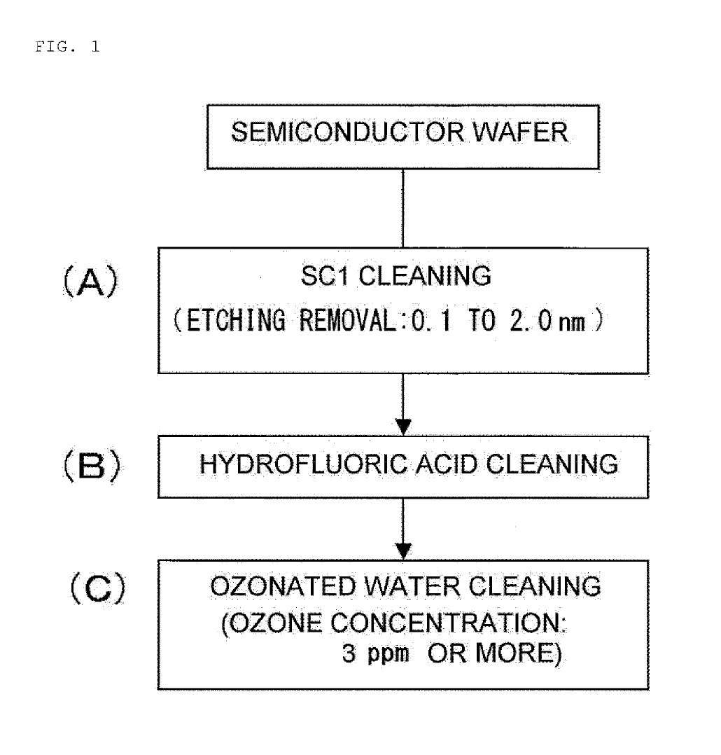

The method for cleaning a semiconductor wafer of the present invention is explained by referring to the drawings, but the present invention is not limited by these. FIG. 1 is a flow chart showing an example of the method for cleaning a semiconductor wafer of the present invention.

As shown in FIG. 1, the whole cleaning steps can be roughly classified into the three steps of (A) a step of cleaning with an SC1 cleaning solution, (B) a step of cleaning with hydrofluoric acid, and (C) a step of cleaning with ozonated water.

In (A) the step of cleaning the semiconductor wafer with an SC1 cleaning solution, the semiconductor wafer is cleaned with the SC1 cleaning solution which is a mixed cleaning solution of aqueous ammonia, a hydrogen peroxide solution and ultrapure water so that an etching removal of the semiconductor wafer becomes 0.1 to 2.0 nm (FIG. 1(A)).

The etching removal of the semiconductor wafer can be adjusted to the above-mentioned range by changing a mixing ratio (volume ratio), a temperature, a cleaning time, and so on of the SC1 cleaning solution. For example, the conditions may be adjusted to the range where the temperature is 25 to 65° C., the mixing ratio is a mixing ratio of ammonia (NH₃ concentration: 28%), a hydrogen peroxide solution (H₂O₂ concentration: 30%) and water being 1:1:5 to 20, and the time of 180 to 360 seconds.

The semiconductor wafer to be cleaned in the present invention is not particularly limited, and a silicon wafer after polishing may be usually mentioned.

If the etching removal of the semiconductor wafer exceeds 2.0 nm, the surface roughness of the wafer is worsened, so that, for example, electric characteristics of an oxide film formed on the silicon wafer are worsened, and bad effects are exerted on detecting particles by a particles counter using scattering of laser light. If the etching removal of the semiconductor wafer is less than 0.1 nm, a sufficient effect of removing particles cannot be obtained.

On the other hand, as mentioned above, in the conventional method for cleaning a semiconductor wafer, if the etching amount with the SC1 cleaning solution was made 2.0 nm or less, there was the problem that particles could not be removed and were left even when the ultrasonic wave was strengthened.

According to the method for cleaning a semiconductor wafer of the present invention, such a problem of remaining the particles which occurs when the etching removal with the SC1 cleaning solution became 2.0 nm or less can be solved by (B) a cleaning step with hydrofluoric acid mentioned below.

Next, (B) the step of cleaning the semiconductor wafer cleaned by the SC1 cleaning solution with hydrofluoric acid is carried out (FIG. 1(B)).

As stated above, according to the conventional cleaning method, when the etching removal with the SC1 cleaning solution was 2.0 nm or less, there was the problem that the particles cannot be removed and were left even when the physical cleaning with ultrasonic wave was strengthened. These left particles were firmly bonded with an oxide film of the wafer surface formed in the SC1 cleaning step. Thus, in the method for cleaning a semiconductor wafer of the present invention, after (A) the SC1 cleaning step, (B) cleaning with hydrofluoric acid (HF cleaning) is additionally carried out to remove all the oxide film formed in (A) the SC1 cleaning step, and the particles firmly bonded with the oxide film can be subjected to lift-off, whereby the remaining particles can be removed. According to the cleaning with hydrofluoric acid, the surface roughness of the wafer is not worsened, so that worsening of the surface roughness of the wafer can be restrained only by worsening of the surface roughness due to the SC1 cleaning in which the etching removal has been reduced.

The concentration of hydrofluoric acid to be used is preferably 0.5 to 3.0%, the temperature is preferably at 10 to 30° C., and the cleaning time is preferably 60 to 180 seconds.

Next, (C) the step of cleaning the semiconductor wafer which has been cleaned by hydrofluoric acid with ozonated water having an ozone concentration of 3 ppm or more is carried out (FIG. 1(C)).

After (B) the above-mentioned cleaning step by the hydrofluoric acid, the surface of the semiconductor wafer becomes a hydrophobic surface which is the state where the particles are likely adhered. Thus, after (B) the step of cleaning with the hydrofluoric acid, by carrying out (C) the cleaning step with ozonated water having an ozone concentration of 3 ppm or more, i.e., by carrying out rinsing with ozonated water having an ozone concentration of 3 ppm or more in a rinsing tank whereby an oxide film is formed on the surface of the silicon wafer within a short period of time to make the surface hydrophilic whereby reattachment of the particles can be suppressed.

The temperature of the ozonated water to be used is preferably 10 to 30° C., and the cleaning time is preferably 60 to 180 seconds.

According to the method for cleaning semiconductor wafer of the present invention, worsening of the surface roughness can be suppressed (for example, the surface roughness Rms (Root Mean Square roughness)) can be made 0.1 nm or less) and particles of the surface of the wafer can be effectively removed.

Incidentally, before (A) the step of cleaning with the SC1 cleaning solution, the semiconductor wafer may be subjected to cleaning with ozonated water. By carrying out the cleaning with the ozonated water, organic materials can be effectively removed and the cleaning effect is more heightened. In addition, rinsing with ultrapure water etc. may be optionally carried out between the respective cleaning steps of (A), (B) and (C).

### EXAMPLES

In the following, the present invention is explained in more detail by referring to Examples and Comparative Examples, but the present invention is not limited by these.

### Examples 1 to 5

In the cleaning of the surface of the silicon wafer after mirror-polishing for removing the abrasives etc., cleaning with an SC1 cleaning solution was firstly carried out, and after rinsing with ultrapure water was carried out, cleanings with HF cleaning and ozonated water were successively carried out, and finally the silicon wafer which had been finished the cleanings was dried.

In the SC1 cleaning, an etching removal with the SC1 cleaning solution was set to 0.1 to 2.0 nm (0.1, 0.6, 1.2, 1.6 and 2.0 (Examples 1 to 5, respectively)) by changing the temperature of the cleaning solution. Incidentally, the SC1 cleaning solution used is a mixed cleaning solution of ammonia, a hydrogen peroxide solution and water with a mixing ratio of 1:1:10. The HF concentration was 1.5%, and the ozone concentration of the ozonated water was made 17 ppm.

### Comparative Examples 1 to 6 and 8

The silicon wafer was cleaned only with the SC1 cleaning solution, and then, dried. The cleaning was carried out by setting the etching removals with the SC1 cleaning solution from 0.1 to 4.5 nm (0.1, 0.6, 1.2, 1.6, 2.0, 3.0 and 4.5 (Comparative Examples 1 to 6 and 8, respectively)).

### Comparative Examples 7 and 9

Cleaning and drying of the silicon wafer were carried out in the same method as in Examples 1 to 5 except that the etching amounts with the SC1 cleaning solution were made 3.0 and 4.5 nm.

### Measurement of Particles on Wafer Surface

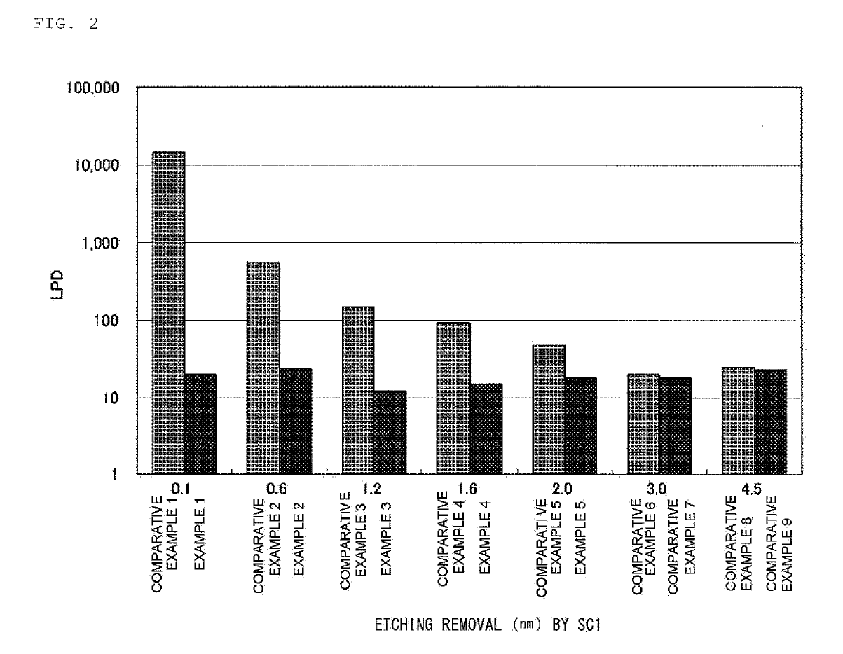

After cleaning and drying were carried out by the above-mentioned Examples and Comparative Examples, comparison of the particles (LPD (Light Point Defect)≧41 nm) on the wafer surface after cleaning was carried out by a particles counter. The results are shown in FIG. 2.

In the cases of the cleaning only with the SC1 cleaning solution in Comparative Examples 1 to 6 and 8, as the etching amount by the SC1 is a little like 0.1 to 2.0 nm, a number of the particles is increasing. On the other hand, in the cleaning method (Examples 1 to 5) of the present invention wherein after cleaning with SC1, HF cleaning and ozonated water rinsing were carried out, it could be confirmed that even when the etching amount was 2.0 nm or less, the same cleaning effects as those of the cases where the etching amounts of 3.0 and 4.5 nm (Comparative Examples 7 and 9) were obtained.

### Measurement of Surface Roughness of Wafer Surface

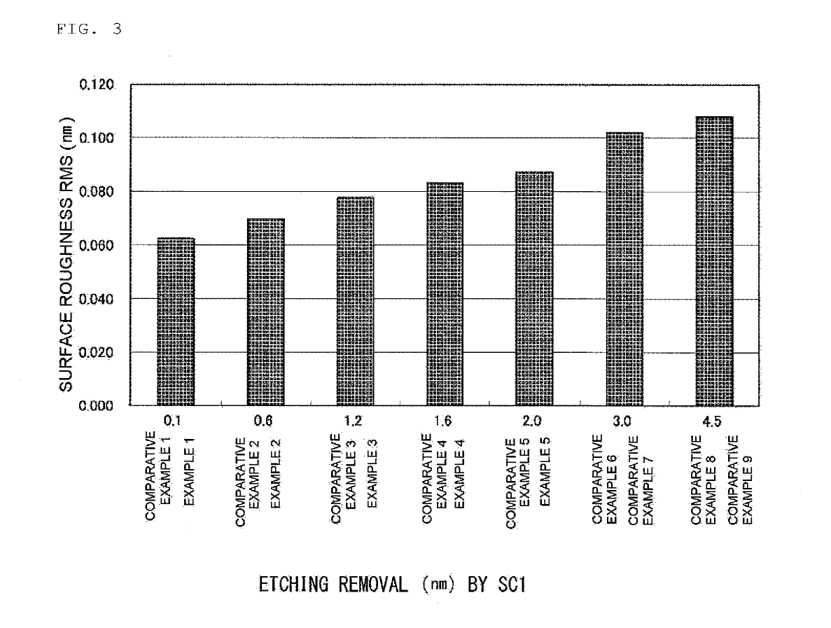

After carrying out the cleaning methods in the above-mentioned Examples 1 to 5 and Comparative Examples 1 to 9, the surface roughness Rms (Root Mean Square roughness) (nm) was measured. The results are shown in FIG. 3.

The surface roughness Rms was 0.102 nm in the etching amount of 3.0 nm, and 0.108 nm in the etching amount of 4.5 nm (Comparative Examples 6 to 9), but was markedly improved as 0.062 nm in the etching amount of 0.1 nm (Comparative Example 1 and Example 1).

The above-mentioned results of the measurement of particles on the silicon wafer surface and the above-mentioned results of the surface roughness of the same are summarized in Table 1.

TABLE 1

| | | Etching removal = | Etching removal > |
|---|---|---|---|
| | | 0.1 to 2. 0 nm | 2.0 nm |
| Cleaning | Cleaning with | (Examples 1 to 5) | (Comparative |
| method | SC1→ | Particle | Examples 7 and 9) |
| | hydro fluoric | measurement | Particle |
| | acid→ | result: good | measurement |
| | ozonated water | Surface roughness | result: good |
| | | measurement | Surface roughness |
| | | result: good | measurement |
| | | | result: no good |
| | Cleaning with | (Comparative | (Comparative |
| | SC1 | Examples 1 to 5) | Examples 6 and 8) |
| | | Particle | Particle |
| | | measurement | measurement |
| | | result: no good | result: good |
| | | Surface roughness | Surface roughness |
| | | measurement | measurement |
| | | result: good | result: no good |

From the results as mentioned above, according to the method for cleaning a semiconductor wafer of the present invention, it can be understood that worsening of the surface roughness of the wafer due to cleaning can be reduced and cleaning of the wafer can be carried out effectively (Examples 1 to 5).

### Example 6, Comparative Example 10

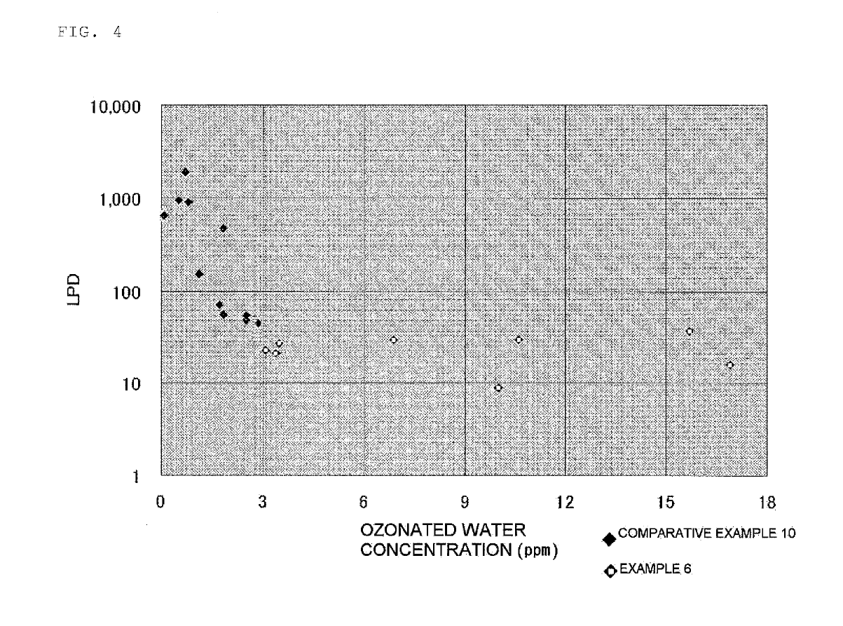

The silicon wafer after mirror-polishing was subjected to SC1 cleaning by making the etching removal 0.6 nm, subsequently cleaning with hydrofluoric acid was carried out. After cleaning with hydrofluoric acid, cleaning with ozonated water was carried out by changing a concentration thereof in a rinsing tank from 0 to 2.8 ppm, and the silicon wafer was dried (Comparative Example 10). Also, the silicon wafer after mirror-polishing was subjected to SC1 cleaning by making the etching removal 0.6 nm, subsequently cleaning with hydrofluoric acid was carried out. After cleaning with hydrofluoric acid, cleaning with ozonated water was carried out by changing a concentration thereof in a rinsing tank from 3.0 to 17 ppm, and the silicon wafer was dried (Example 6). The particles on the wafer after cleaning were measured by a wafer surface detecting apparatus. Incidentally, the SC1 cleaning solutions used in Example 6 and Comparative Example 10 were a mixed cleaning solution comprising ammonia, a hydrogen peroxide solution and water with a mixing ratio of 1:1:10, and a hydrofluoric acid concentration of 1.5%. The results are shown in FIG. 4.

When the ozone concentration of the ozonated water is 3 ppm or more (Example 6), the surface of the silicon wafer can be oxidized within a short period of time, i.e., can be changed from a hydrophobic surface to a hydrophilic surface, so that it can be understood that the number of the particles is stable as around 20.

It must be stated here that the present invention is not restricted to the embodiments shown by Examples. The embodiments shown by Examples are merely examples so that any embodiments composed of substantially the same technical concept as disclosed in the claims of the present invention and expressing a similar effect are included in the technical scope of the present invention.

1. A method for cleaning a semiconductor wafer which comprises the steps of:
cleaning the semiconductor wafer with an SC1 cleaning solution,
cleaning the semiconductor wafer cleaned by the SC1 cleaning solution with hydrofluoric acid, and
cleaning the semiconductor wafer cleaned by the hydrofluoric acid with ozonated water having an ozone concentration of 3 ppm or more,
wherein an etching removal of the semiconductor wafer with the SC1 cleaning solution is made 0.1 to 2.0 nm.
